(19) United States
(12) Patent Application Publication
(10) Pub. No.: US 2005/0258424 A1
(43) Pub. Date: Nov. 24, 2005

(54) Integrated capacitor

(76) Inventors: Bernard Sautreuil, Saint Egreve (FR); Michel Marty, Saint Paul De Varces (FR); Jerome Bonnouvrier, Grenoble (FR); Jean-Francois Carpentier, Grenoble (FR)

Correspondence Address: GRAYBEAL, JACKSON, HALEY LLP, 155 - 108TH AVENUE NE, SUITE 350, BELLEVUE, WA, 98004-5901, US

(21) Appl. No.: 11/079,018

(22) Filed: Mar. 10, 2005

(30) Foreign Application Priority Data
Mar. 10, 2004 (FR) 04/50483

(51) Int. Cl. H01L 21/00

(52) U.S. Cl. 257/71

(57) ABSTRACT

A capacitor made in an upper part of a semiconductor substrate, comprising at least one lightly-doped N-type semiconductor layer having its upper surface comprising a heavily-doped P-type region delimited by an insulation area, a contact of the capacitor being formed by a metal layer buried immediately under the N-type semiconductor layer and by at least one vertical metal contact crossing the semiconductor layer down to the metal layer, the contact reaching the surface of the semiconductor layer outside of the P-type region.

### Priority Claim

This application claims priority from French patent application No. 04/50484, filed Mar. 10, 2004, which is incorporated herein by reference.

### BACKGROUND OF THE INVENTION

1. Field of the Invention

The present invention relates to a structure and a method for manufacturing an integrated capacitor in a semiconductor substrate. More specifically, the present invention relates to such a capacitor having a capacitance which varies according to the voltage applied thereacross.

2. Discussion of the Related Art

Variable capacitance capacitors are conventionally made in the form of a PN junction having its space charge area forming an insulator of variable thickness. In practice, the desired nominal value of the capacitance is adjusted by forming several PN junctions. For this purpose, a common cathode is generally made in the form of an N-type semiconductor layer in which are formed several P-type anode regions.

FIGS. 1A to 1D illustrate partial simplified cross-sectional views of different steps of the forming of such a capacitor according to a known method.

As illustrated in FIG. 1A, the method starts from a single-crystal silicon substrate 1, for example, lightly P-type doped. It is started with the successive forming on the upper surface side of the substrate of a very heavily doped N-type single-crystal silicon layer 2 (N⁺) and of an N-type doped single-crystal silicon upper layer 3 (N).

At the next steps, illustrated in FIG. 1B, a deep insulation area 5 is formed in layers 3 and 2 and a portion of substrate 1. Insulation area 5 is a trench having its walls and its bottom covered with a thin silicon oxide layer 6, the remaining cavity being filled with polysilicon 7: In the rest of the description, only the steps implemented in the internal portion defined by insulation area Swill be considered.

Then, as illustrated in FIG. 1C, shallow insulation areas of silicon oxide filled trench type are formed in the sole layer 3. More specifically, a peripheral area 9 which extends on either side of deep insulation area 5 is formed. Small-size insulation areas 10 which enable defining separate regions at the surface of layer 3 are also formed inside of the portion of layer 3 defined by deep area 5. Heavily-doped P-type regions 12 (P⁺) are also formed. Regions 12 are formed so that each region 12 is delimited by an insulation area 10. A portion 14 of layer 3 is maintained between two areas 10 peripheral to separate regions 12. A portion 14 is also maintained in peripheral area 9 and insulation areas 10.

Then, as illustrated in FIG. 1D, N-type dopants are implanted to form, at the surface of portions 14, very heavily-doped N-type regions 15 (N⁺⁺) and, between these regions 15 and buried layer 2, heavily-doped N-type vertical regions 16.

The method then carries on with the forming of anode and cathode contact metallizations, not shown, solid with regions 12 and 15, respectively.

The dimensions and the doping levels of the different layers and regions of FIG. 1D typically are the following:
layer 2: from 100 to 200 nm, N-type doping ranging between 10¹⁹ at/cm³ and 10²⁰ at/cm³;
layer 3: from 100 to 200 nm, N-type doping ranging between 10¹⁵ and 10^{18 at/cm}³;
regions 12 and 15: of a depth substantially equal to that of insulation areas 10, on the order of from 20 to 50 nm, respectively P and N-type doped on the order of from 10²⁰ to 10²¹ at/cm³; and
vertical regions 16: N-type doped on the order of from 10¹⁷ to 10¹⁸ at/cm³.

A disadvantage of the capacitor obtained by means of the previously described method is the high cathode access resistance. Indeed, excluding the metallization, which has a resistance equal to that of the anode metallization, the cathode contact is formed of the succession of surface region 15, of a vertical region 16, and of buried layer 2. Thus, considering the previous dimension and doping characteristics, the cathode access resistance is on the order of from 70 to 80 Ω.

### SUMMARY OF THE INVENTION

An aspect of the present invention provides an integrated capacitor with a reduced cathode resistance.

Another aspect of the present invention provides such a capacitor without increasing the anode resistance.

Another aspect of the present invention provides a method for manufacturing such a capacitor.

According to another aspect of the present invention provides a capacitor is made in an upper part of a semiconductor substrate, comprising at least one lightly-doped N-type semiconductor layer having its upper surface comprising a heavily-doped P-type region delimited by an insulation area, a contact of the capacitor being formed by a metal layer buried immediately under the N-type semiconductor layer and by at least one vertical metal contact crossing the semiconductor layer down to the metal layer, the contact reaching the surface of the semiconductor layer outside of the P-type region.

According to a further aspect of the present invention, the metal layer and the metal contact are formed of a same metallic material selected from the group comprising tungsten, titanium nitride, titanium, copper, and alloys of these materials.

According to another aspect of the present invention, a method forms a capacitor of the type comprising, in an upper portion of a semiconductor substrate, a lightly-doped N-type semiconductor layer having its upper surface comprising at least one heavily-doped P-type region delimited by an insulation area, comprising a step of forming of a metal layer buried immediately under the semiconductor layer and of at least one vertical metal contact extending into the semiconductor layer down to the metal layer, the contact reaching the surface of the semiconductor layer outside of the region.

According to an aspect of the present invention, the step of forming the layer and the metal contact comprises the steps of:
opening in the semiconductor layer, outside of the region, at least one vertical well to reach an intermediary buried layer between the substrate and the semiconductor layer,
   removing the intermediary layer, and
   depositing a metallic material to fill the recess resulting from the removal of the buried layer as well as the vertical well.

According to a further aspect of the present invention, the step of deposition of the metallic material to fill the recess and the vertical well consists of conformally depositing a metallic material and of performing a chemical-mechanical polishing.

According to another aspect of the present invention, the step of removing the intermediary layer is followed by a selective epitaxy of a very strongly conductive thin semiconductor layer on the sole exposed portions of the semiconductor layer in the well and in the recess.

According to one aspect of the present invention, the epitaxial semiconductor layer has a thickness smaller than 10 nm.

According to yet another aspect of the present invention, the intermediary layer is a single-crystal silicon-germanium layer comprising a germanium proportion of at least 20%.

According to another aspect of the present invention, the intermediary layer is an insulating layer selectively etchable with respect to the substrate and with respect to the semiconductor layer.

The foregoing aspects of the present invention will be discussed in detail in the following non-limiting description of specific embodiments in connection with the accompanying drawings.

### BRIEF DESCRIPTION OF THE DRAWINGS

FIGS. 1A to 1D illustrate, in partial simplified cross-section view, different steps of the forming of a known capacitor; and

FIGS. 2A to 2E illustrate, in partial simplified cross-section view, different steps of a method for forming a capacitor according to embodiments of the present invention.

### DETAILED DESCRIPTION

The following discussion is presented to enable a person skilled in the art to make and use the invention. Various modifications to the embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

For clarity, same elements have been designated with same reference numerals in the different drawings and, further, as usual in the representation of integrated circuits, the various drawings are not to scale.

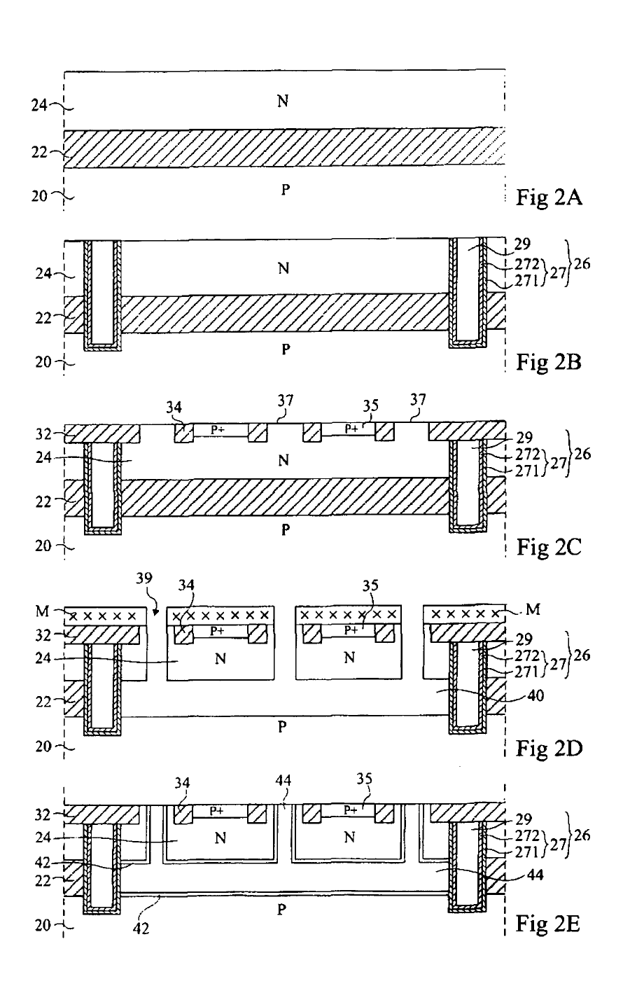

As illustrated in FIG. 2A, a method according to one embodiment of the present invention starts from a single-crystal semiconductor substrate 20, for example, lightly-doped P-type silicon, covered with two successive layers 22 and 24. The (N) surface layer 24 is a single-crystal semiconductor layer, for example, lightly-doped N-type silicon. Intermediary layer 22 is made of any material selectively etchable with respect to underlying substrate 20 and to superposed layer 24. According to an embodiment, intermediary layer 22 is an insulating silicon oxide layer (SiO₂). Layer 24 then is of silicon-on-insulator type. According to another embodiment, layer 22 is a single-crystal silicon-germanium semiconductor layer comprising a germanium proportion of at least 20%.

At the next step illustrated in FIG. 2B, a deep insulation ring-shaped region 26 is formed in the stacking of layers 24 and 22 and in a portion of underlying substrate 20. Area 26 is of trench type with its vertical walls and its bottom covered with an insulating layer 27, the remaining cavity being filled with a filling layer, for example, polysilicon 29. Preferably, insulating layer 27 is a multilayer formed of a lower layer 271 and of an upper layer 272. The nature of layer 27 or of lower layer 271 is selected so that layer 22 is selectively etchable with respect thereto. For example, when intermediary layer 22 is a silicon oxide layer, lower layer 271 is a silicon nitride layer and upper layer 272 is a silicon oxide layer. In the rest of the description, only the steps implemented in the internal portion defined by deep insulation area 26 will be considered.

Then, as illustrated in FIG. 2C, shallow insulation areas are formed in the sole surface layer 24. Thus, a peripheral insulation area 32 which extends on either side of deep insulation area 26 is formed. Small-size insulation areas 34 are also formed to define several separate regions at the surface of layer 24. Heavily-doped P-type regions (P⁺) 35 are formed at the surface of layer 24. Each region 35 is delimited by an area 34. A portion 37 of layer 24 is maintained between two areas 34 peripheral to separate regions 35. A portion 37 is also maintained between peripheral area 32 and insulation areas 34.

At the next steps illustrated in FIG. 2D, wells 39 reaching the upper surface of intermediary layer 22 are formed by means of a mask M in portions 37 of layer 24. Layer 22 is then removed by an appropriate etch method. A recess 40 is thus formed immediately under layer 24.

Then, as illustrated in FIG. 2E, after removal of mask M, an epitaxy is performed to grow a very thin, very heavily-doped N-type layer 42, on the order of from 5 to 10 nm, with a concentration on the order of 10²¹ at/cm³. Then, a metallic conductive material 44 is deposited, to fill recess 40 and wells 39. For this purpose, a layer of metallic material 44 is for example deposited, then leveled by chemical-mechanical polishing (CMP). The CMP is completed, if required, by an etching capable of removing layer 42 from the surface of anode regions 35. It should be noted that previously-formed layer 42 is necessary to avoid the forming of a Schottky-type junction between metallic material 44 and layer 24.

A capacitor formed by the placing in parallel of PN junctions formed between common cathode terminal 24 and individual anode regions 35 having an advantageously reduced cathode access resistance is thus obtained. Indeed, this access resistance is the metal contact resistance, the resistance of thin layer 42 being negligible due, on the one hand, to its very small thickness which is limited to the bare essentials, and to its high doping. The cathode access resistance then is on the order of from 17 to 20 Ω.

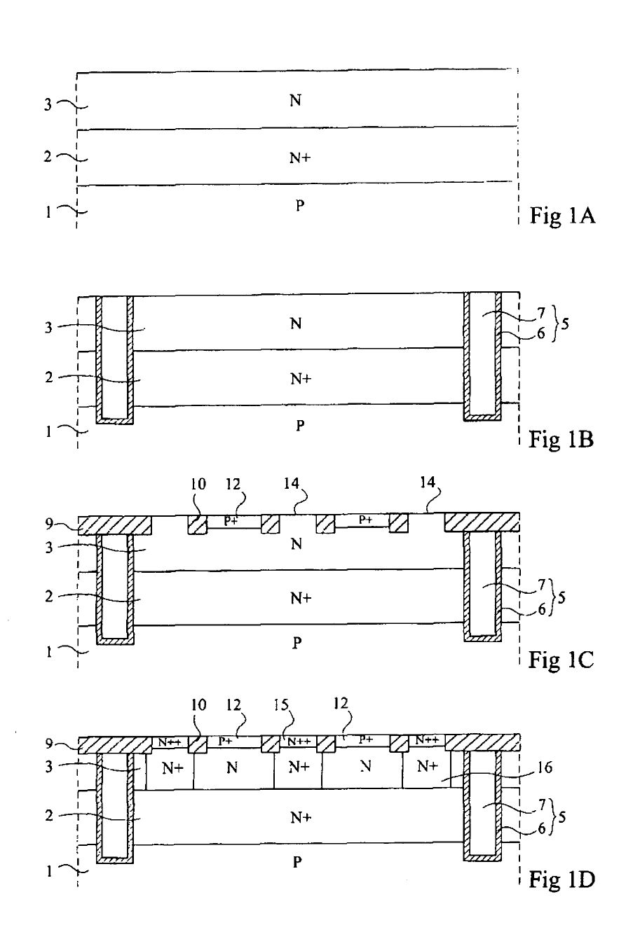

It should be noted that a method for forming a capacitor according to an embodiment of the present invention has the advantage of being able to directly start from a silicon-on-insulator substrate, as indicated previously. This is advantageous since the use of such substrates is more and more frequent in current technological processes. Such a substrate is more difficult to use to form a known capacitor such as described in relation with FIGS. 1A-D since it would then be necessary to start with the successive forming of layers 2 and 3. According to embodiments of the present invention, it is enough to have layer 24 which corresponds to layer 2 of a known capacitor.

According to an embodiment not shown, the upper surface of substrate 20 of FIGS. 2A to 2E initially underlying intermediary layer 22 is lightly N-type doped. Such a doping, ranging for example between 10¹² and 10¹⁴ at/cm³, enables improving the insulation of cathode 24-45 of the capacitor and of substrate 20 with respect to the insulation obtained by the sole layer 42.

Of course, embodiments of the present invention are likely to have various alterations, improvements, and modifications which will readily occur to those skilled in the art. In particular, the sole steps of implementation in the portion internal to deep insulation trenches 26, in which portion the capacitor according to the present invention is formed, have been described from FIG. 2C. It will however be within the abilities of those skilled in the art to implement outside of this portion any method step necessary to the forming of other elements (switches, bipolar transistors, MOS transistors, inductances, resistors, etc.).

Further, it will be within the abilities of those skilled in the art to adapt the number and the dimensions in top view of wells 39 and the deposition conditions of material 44 which are selected to enable uniform filling of recess 40 between substrate 20 and layer 24. The number of wells 39 will also have to be sufficiently limited to ensure the cohesion of layer 24 to avoid its falling into recess 40 after removal of underlying intermediary layer 22. This falling is avoided by the fact that layer 24 bears against deep ring-shaped insulation region 26.

Further, it has been considered in relation with FIG. 2E that layer 42 is non-selectively formed on all the silicon surfaces. However, to decrease the risks of damaging the surface of anodes 35, a selective growth may also be performed on the sole N-type surfaces of region 24 in wells 39 and recess 40.

It will be within the abilities of those skilled in the art to make any necessary material and thickness modification in a given technological process. Thus, it will be within the abilities of those skilled in the art to adapt the materials of deep insulating regions 26. In particular, it will be within the abilities of those skilled in the art to adapt external insulating material 27 or 271 of areas 26 to the exact nature of the utilized intermediary layer 22. Thus, when layer 22 is a silicon oxide layer, as previously mentioned, it is indispensable for layer 27 or 271 to be made of a material such as silicon nitride which is not etched on removal (FIG. 2D) of layer 22. However, when layer 22 is silicon-germanium, layer 27 may be reduced to the sole silicon oxide layer 272.

Similarly, in the case of a silicon-germanium intermediary layer 22, it will be within the abilities of those skilled in the art to adapt its germanium concentration, preferably grater than 20%, to the selective removal constraints on layer 22 with respect to underlying substrate 20 and with respect to superposed layer 24.

Similarly, it will be within the abilities of those skilled in the art to adapt the utilized conductive materials to a specific technological process. In particular, those skilled in the art will adapt metallic material 44 to the constraints of deposition in recess 40 through wells 39 and to the desired electric performances. Conductive material 44 will be selected from the group of metallic materials currently used for a considered line. In the case of silicon, material 44 will for example be copper, tungsten, titanium, titanium nitride, or an alloy of these metals.

It will also be within the abilities of those skilled in the art to adapt the thicknesses and doping levels of the various semiconductor layers and/or regions to the desired electric performances. In particular, it will be within the abilities of those skilled in the art to adjust the doping level of cathode 24 of the capacitor. For example, after forming of deep insulation area 26 and/or surface insulation area 32 and/or 34, an implantation/diffusion of N-type dopants will be performed.

It should be noted that a capacitor according to embodiments of the present invention is likely to have many applications. For example, such a capacitor may be used in multiband receiver architectures to optimize the operation of filters of the receiver according to a desired application, for example, a high-frequency communication.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A capacitor made in an upper part of a semiconductor substrate, comprising at least one lightly-doped N-type semiconductor layer having its upper surface comprising a heavily-doped P-type region delimited by an insulation area, wherein a contact of the capacitor is formed by a metal layer buried immediately under the N-type semiconductor layer and by at least one vertical metal contact crossing the semiconductor layer down to the metal layer, the contact reaching the surface of the semiconductor layer outside of the P-type region.

2. The capacitor of claim 1, wherein the metal layer and the metal contact are formed of a same metallic material selected from the group consisting of tungsten, titanium nitride, titanium, copper, and alloys of these materials.

3. A method for forming a capacitor of the type comprising, in an upper portion of a semiconductor substrate, a lightly-doped N-type semiconductor layer having its upper surface comprising at least one heavily-doped P-type region delimited by an insulation area, comprising a step of forming a metal layer buried immediately under the semiconductor layer and at least one vertical metal contact extending into the semiconductor layer down to the metal layer, the contact reaching the surface of the semiconductor layer outside of said region.

4. The method of claim 3, wherein the step of forming the layer and the metal contact comprises the steps of:
opening in the semiconductor layer, outside of the region, at least one vertical well to reach an intermediary buried layer between the substrate and the semiconductor layer;
removing the intermediary layer; and
depositing a metallic material to fill the recess resulting from the removal of the buried layer as well as the vertical well.

5. The method of claim 4, wherein the step of deposition of the metallic material to fill the recess and the vertical well consists of conformally depositing a metallic material and of performing a chemical-mechanical polishing.

6. The method of claim 4, wherein the step of removing the intermediary layer is followed by a selective epitaxy of a very strongly conductive thin semiconductor layer on the sole exposed portions of the semiconductor layer in the well and in the recess.

7. The method of claim 6, wherein the epitaxial semiconductor layer has a thickness smaller than 10 nm.

8. The method of claim 4, wherein the intermediary layer is a single-crystal silicon-germanium layer comprising a germanium proportion of at least 20%.

9. The method of claim 4, wherein the intermediary layer is an insulating layer selectively etchable with respect to the substrate and with respect to the semiconductor layer.

10. A capacitor formed in a substrate layer, the capacitor comprising:
a first semiconductor layer formed adjacent the substrate layer, the first semiconductor layer having a first conductivity type;
at least one region formed in the first semiconductor layer, each region having a second conductivity type opposite that of the first conductivity type; and
a buried metal layer formed between the first semiconductor layer and the substrate layer.

11. The capacitor of claim 10 wherein the substrate layer comprises a lightly-doped P-type layer, the first semiconductor layer comprises a lightly-doped N-type layer, and each region comprises a heavily-doped P-type region.

12. The capacitor of claim 10 wherein the metal layer further comprises at least one vertical contact portion extending to an upper surface of the first semiconductor layer in which the regions are formed, each vertical contact portion reaching the upper surface of the first semiconductor layer separated from the regions.

13. The capacitor of claim 12 wherein the metal layer and each vertical contact portion are formed from a metallic material selected from the group consisting of tungsten, titanium nitride, titanium, copper, and alloys of these materials.

14. The capacitor of claim 10 further comprising a deep ring-shaped trench isolation region formed in the substrate layer, buried metal layer, and the first semiconductor layer, the isolation region surrounding the regions in the first semiconductor layer.

15. The capacitor of claim 10 further comprises a thin epitaxial layer formed between the substrate layer and the buried metal layer and formed between the first semiconductor layer and the buried metal layer.

16. A method of forming a capacitor in a substrate including a substrate layer, an intermediary layer formed on the substrate layer, and a first semiconductor layer having a first conductivity type, the method comprising:
forming a trench insulation region surrounding a portion of a surface of the first semiconductor layer, the trench isolation region extending through the first semiconductor layer and the intermediary layer;
forming in the portion of the first semiconductor layer surrounded by the trench insulation region at least one region having a second conductivity type that is opposite that of the first conductivity type;
forming at least one well extending from the surface of the first semiconductor layer to a surface of the intermediary layer;
removing the intermediary layer to form a recess between the substrate layer and portions of first semiconductor layer in which the regions are formed; and
forming a metallic layer in the recess and in each well.

17. The method of claim 16 further comprising forming shallow insulation regions in the first semiconductor layer, each shallow insulation region delimiting a corresponding region formed in the first semiconductor layer.

18. The method of claim 16 wherein the intermediary layer comprises any material that is selectively removable with respect to the substrate layer and the trench insulation region.

19. The method of claim 18 wherein the intermediary layer is a material selected from the group consisting of silicon oxide and a single crystal silicon germanium material.

20. The method of claim 16 wherein the trench insulation region comprises a ring-shaped region formed extending through the first semiconductor layer, intermediary layer, and into the substrate layer.

21. The method of claim 16 wherein forming at least one well extending from the surface of the first semiconductor layer to a surface of the intermediary layer comprises forming a plurality of wells to form isolated portions of the first semiconductor layer when the intermediary layer is removed, each isolated portion of the first semiconductor layer containing a respective region of the second conductivity type.

22. The method of claim 21 further comprising forming a very thin and very heavily doped epitaxial layer on the isolated portions of the first semiconductor layer and on the substrate layer prior to the forming the metallic layer.

23. The method of claim 16 wherein the first conductivity type is N-type and the second conductivity type is P-type.

24. The method of claim 16 wherein forming a trench insulation region comprises:
forming a trench extending through the first semiconductor layer, the intermediary layer, and extending into the substrate layer;
forming on vertical portions and a bottom portion of the trench an insulation layer, a cavity remaining within the trench after formation of the insulation layer and the insulation layer being selectively removable with respect to the intermediary layer; and
forming a polysilicon layer in the cavity.

25. The method of claim 24 wherein forming the insulation layer comprises:
forming a lower insulation layer on the portions of the trench, the lower layer being selectively removable with respect to the intermediary layer; and
forming an upper insulation layer on the lower insulation layer.

26. An electronic system, comprising:
an electronic subsystem including a capacitor formed in a substrate layer, the capacitor including,
a first semiconductor layer formed adjacent the substrate layer, the first semiconductor layer having a first conductivity type;
at least one region formed in the first semiconductor layer, each region having a second conductivity type opposite that of the first conductivity type; and
a buried metal layer formed between the first semiconductor layer and the substrate layer.

27. The electronic system of claim 26 wherein the electronic subsystem comprises a multiband receiver.
